(19) United States
(12) Patent Application Publication
(10) Pub. No.: US 2002/0011620 A1
(43) Pub. Date: Jan. 31, 2002

(54) Capacitor having a TaON dielectric film in a semiconductor device and a method for manufacturing the same

(76) Inventor: Seung Kyu Han, Seoul (KR)

Correspondence Address: BIRCH STEWART KOLASCH & BIRCH, PO BOX 747, FALLS CHURCH, VA, 22040-0747, US

(21) Appl. No.: 09/870,752

(22) Filed: Jun. 1, 2001

(30) Foreign Application Priority Data
Jun. 1, 2000 (KR) 2000-30086

(51) Int. Cl. H01L 21/8242; H01L 27/108

(52) U.S. Cl. 257/310; 438/240

(57) ABSTRACT

A method of manufacturing a capacitor in a semiconductor device is provided. The capacitor is manufactured by depositing a Ta metal film on a semiconductor substrate, crystallizing the Ta metal film, forming a lower electrode by pattering a predetermined portion of the Ta metal film, forming a TaON film on the lower electrode, and forming an upper electrode on the TaON film. Thus, high capacitance can be obtained accompanied by a reduction in leakage current.

### BACKGROUND OF THE INVENTION

1. Field of the Invention

The invention relates to a semiconductor device with a capacitor having a TaON dielectric film and a method for manufacturing the same, and more particularly, to a semiconductor device with a capacitor having a TaON dielectric film which can improve the leakage current property while reducing the equivalent thickness of the dielectric film, and to a method for manufacturing the same.

2. Description of the Related Art

The ever-increasing number of memory cells constituting a DRAM semiconductor device requires the area occupied by each memory cell to be gradually reduced. However, the capacitor formed in each memory cell requires sufficient capacitance to accurately read the stored data. Accordingly, a state-of-the-art DRAM semiconductor device needs a memory cell capacitor having a larger capacitance while occupying less area.

The capacitance of a capacitor can increase by forming a dielectric film from an insulation material having a high permittivity, or by enlarging the surface area of a lower electrode. In the present highly integrated DRAM semiconductor device, a Ta oxide (Ta₂O₅) film exhibiting permittivity higher than a NO (nitric oxide) film is used as a dielectric, and a three-dimensional lower electrode is formed.

However, since the Ta oxide film used as the dielectric film has an unstable stoichiometry, an oxidation process to stabilize the dielectric film after deposition should be performed. Here, the Ta oxide film easily reacts with the lower electrode during the oxidation process so that the thickness of the dielectric film is increased while capacitance is reduced. Also, since the Ta oxide film is formed by using an organic Ta metal material as a precursor, a large amount of carbon and carbon compounds remain in the film so that leakage current easily occurs.

To solve the above problem of the Ta oxide film, the applicant has suggested a capacitor using a TaON (tantalum oxynitride) film as a dielectric, and has filed a patent application therefor in the Korean Patent Office on Jun. 25, 1999. The capacitor using the TaON film as a dielectric film is shown in FIG. 1.

Referring to FIG. 1, a interlayer insulation film 12 having a contact hole 14 for exposing a certain area of a junction area (not shown) of transistors is formed on a semiconductor substrate 10 where transistors (not shown) are formed. A lower electrode 15 of a capacitor is formed inside the contact hole 14 and on the interlayer insulation film 12 to contact the exposed junction area. The lower electrode 15 is formed of a doped polysilicon film, for example, and may have a cylindrical, pin or stack shape. The surface of the lower electrode 15 is in-situ plasma processed or HF etch processed to prevent the generation of a natural oxide film. As a dielectric film, a TaON film 16 is formed on the surface of the lower electrode 15 and the interlayer insulation film 12. Here, the TaON film 16 is formed by a surface chemical reaction between Ta chemical vapor made by vaporizing a precursor such as Ta(OC₂H₆), NH₃ gas or O₂ gas. Next, the TaON film 16 is heat-treated at a predetermined temperature and crystallized. Then, an upper electrode 17 is formed on the TaON film 16. The upper electrode 17 is a metal layer formed of a material such as TiN, TaN, W, WN, WSi, Ru, RuO₂, Ir, IrO₂ or Pt.

The TaON film 16 has a very high permittivity (about 20-25) and a stable combination structure of Ta—O—N, so that no stabilizing oxidation process after deposition is needed. Also, since the TaON film 16 has a very low oxidation reaction property, a natural film scarcely generates during the subsequent heat treatment process so that the thickness of the dielectric film does not increase.

However, since the lower electrode is formed into a doped polysilicon film, the conventional capacitor has the following disadvantages.

In general, it is well known that a doped polysilicon film is a material capable of exhibiting a superior oxidation reaction. Thus, after the TaON film 16 is formed, a heat treatment process is performed to crystallize the TaON film 16. In doing so, the surface of the lower electrode 15 naturally oxidizes and an undesired natural oxide film is generated. Such a natural oxide film is formed of SiO₂ showing a lower permittivity. Thus, when the thickness of the dielectric film is increased, the dielectric property deteriorates and the capacitance is consequently lowered.

To solve this problem, another method for reducing the thickness T_{OX} of the dielectric film has been suggested. However, when the thickness of the dielectric film is reduced, the leakage current proportionally increases to deteriorate the capacitor's performance.

### SUMMARY OF THE INVENTION

To solve the above problems, the invention, in part, provides a capacitor in a semiconductor device, the capacitor having a TaON dielectric film that can secure high capacitance while reducing leakage current.

Another objective of the invention, in part, provides a method for manufacturing the capacitor having a TaON dielectric film in a semiconductor device.

To achieve the above objectives, the invention, in part, provides a capacitor in a semiconductor device having a lower electrode formed of a Ta metal film on a semiconductor substrate, a TaON dielectric film formed on the lower electrode, and an upper electrode formed on the TaON dielectric film.

To achieve another objective, the invention, in part, provides a method of manufacturing a capacitor in a semiconductor device having the steps of depositing a Ta metal film on a semiconductor substrate, crystallizing the Ta metal film, forming a lower electrode by pattering a predetermined portion of the Ta metal film, forming a TaON film on the lower electrode, and forming an upper electrode on the TaON film.

To achieve another objective, the invention, in part, provides a method of manufacturing a capacitor in a semiconductor device comprising the steps of depositing a Ta metal film on a semiconductor substrate, crystallizing the Ta metal film, forming a lower electrode by pattering a predetermined portion of the Ta metal film, forming a TaON film on the lower electrode, crystallizing the TaON metal film, and forming an upper electrode on the TaON film, in which a step of forming a TaN (tantalum nitride) film on the surface of the Ta metal film is provided between the step of depositing the Ta metal film and the step of crystallizing the Ta metal film, or between the step of crystallizing the Ta metal film and the step of forming the lower electrode.

It is to be understood that both the foregoing general description and the following detailed description are exemplary and explanatory and are intended to provide further explanation of the invention as claimed.

### BRIEF DESCRIPTION OF THE DRAWINGS

The above objectives and advantages of the present invention will become more apparent by describing in detail a preferred embodiment thereof with reference to the attached drawings in which:

FIG. 1 is a sectional view showing a conventional capacitor having a TaON dielectric layer in a semiconductor device; and

FIG. 2A shows a sectional view of a method of manufacturing a semiconductor device capacitor having a TaON dielectric layer according to an embodiment of the invention.

FIG. 2B shows a sectional view of a method of manufacturing a semiconductor device capacitor having a TaON dielectric layer according to an embodiment of the invention.

FIG. 2C shows a sectional view of a method of manufacturing a semiconductor device capacitor having a TaON dielectric layer according to an embodiment of the invention.

FIG. 2D shows a sectional view of a method of manufacturing a semiconductor device capacitor having a TaON dielectric layer according to an embodiment of the invention.

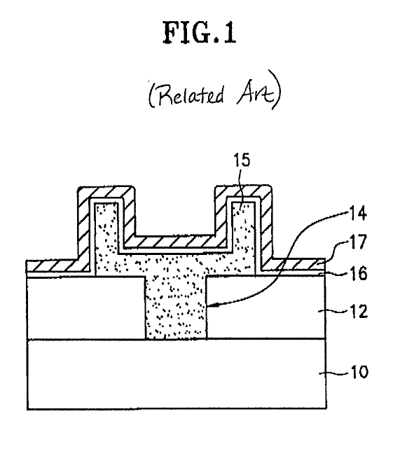

These accompanying drawings are included to provide a further understanding of the invention. The drawings illustrate embodiments of the invention and together with the description serve to explain the principles of the embodiments of the invention.

### DETAILED DESCRIPTION OF THE INVENTION

Advantages of the present invention will become more apparent from the detailed description given herein after. However, it should be understood that the detailed description, while indicating preferred embodiments of the invention, are given by way of illustration only, since various changes and modifications within the spirit and scope of the invention will become apparent to those skilled in the art from this detailed description.

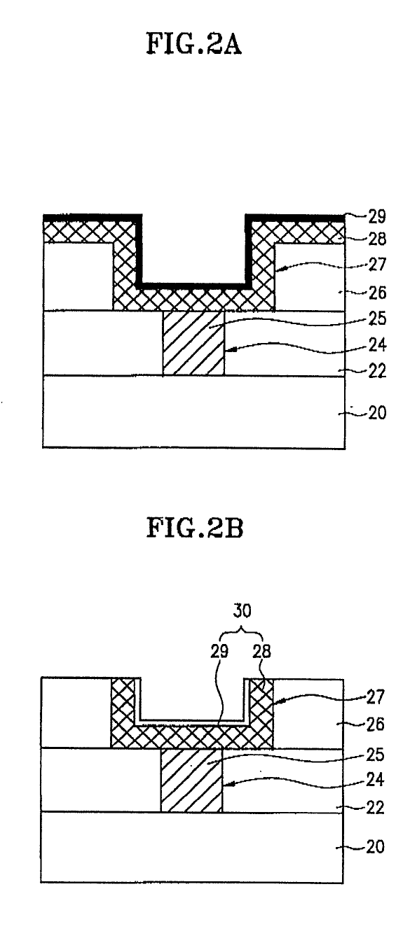

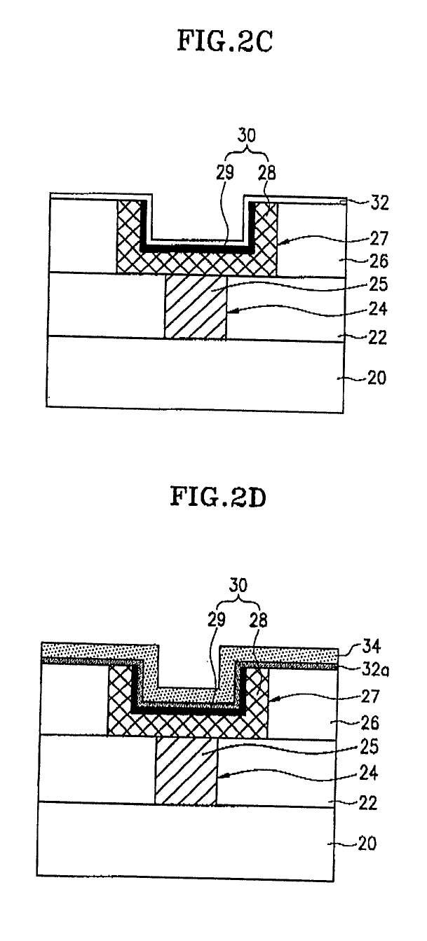

FIGS. 2A through 2D are sectional views for explaining a method for manufacturing a semiconductor device capacitor having a TaON dielectric film according to the invention.

Referring to FIG. 2A, a first interlayer insulation film 22 having a contact hole 24 through which portion of a junction area (not shown) of a transistor is formed on a semiconductor substrate 20 where transistors (not shown) are formed. A contact plug 25 is formed using well-known technology so as to contact the junction area in the contact hole 24. Then, a second interlayer insulation film 26 is formed on the contact plug 25 and the first interlayer insulation film 22. The second interlayer insulation film 26 is partially etched so that the contact plug 25 and a portion of the first interlayer insulation film 22 around the contact plug 25 can be open, forming a concave portion 27. The surfaces of the first and second interlayer insulation films 22 and 26 and the contact plug 25 are cleaned by using HF or BOE solution in order to remove by-products formed during the processes and residue from etching.

Then, as a material for a lower electrode, a Ta metal film 28 having very low reactivity with oxygen is deposited to a predetermined thickness on the second interlayer insulation film 26, the contact plug 25 and a portion of the first interlayer insulation film 22 around the contact plug 25. The Ta metal film 28 is formed by a direct current magnetron sputtering method at a pressure of about 0.01 to 0.4 torr. Here, argon (Ar) gas is injected in a sputtering chamber (not shown) as a reaction gas to form a plasma inside of the sputtering chamber. To excite the reaction gas to a plasma state, a high frequency electric power (RF) of about 30 to 400 W is applied. Preferably, the Ar gas is provided at about 10 to 1000 sccm.

Next, the temperature of the inside of the sputtering chamber is raised to about 600 to 750° C. and N₂ or NH₃ gas is injected. The resulting substrate having formed the Ta metal film 28 then undergoes a heat treatment for about 5 to 30 minutes. Then, the Ta metal film 28 deposited in-situ in an amorphous state changes to a crystallized state. The crystallization process may be performed by heat treatment at a temperature of about 300 to 500° C. for about 1 to 30 minutes after plasma is excited inside the sputtering chamber.

Next, to prevent natural oxidation of the surface of the Ta metal film 28, a TaN film 29 is formed on the surface of the crystallized Ta metal film 28. The TaN film 29 is formed in-situ by providing a gas including nitrogen in the sputtering chamber where the Ta metal film 28 is formed. In particular, the temperature and the pressure in the sputtering chamber are kept at about 300 to 450° C. and about 0.01 to 0.4 torr, respectively, and NH₃ gas at a flow rate of about 10 to 1000 sccm is provided into the sputtering chamber. Thus, the surface of the Ta metal film 28 is nitrified so that the TaN film 29 is formed. The TaN film 29 has superior anti-nitrification.

As shown in FIG. 2B, the TaN film 29 and the Ta metal film 28 are CMP (chemical mechanical polishing) processed so that they can remain only in the concave portion 27 of the second interlayer insulation film 26, thus forming a lower electrode 30. Here, the CMP processing is performed until the surface of the second interlayer insulation film 26 is exposed so that the lower electrode 30 is electrically insulated from other nearby lower electrodes 30.

Referring to FIG. 2C, a predetermined cleaning process is performed with respect to the surfaces of the lower electrode 30 and the second interlayer insulation film 26 to remove a natural oxidation film generated during the CMP process. Then, a TaON film 32 as a dielectric is formed on the surface of the lower electrode 30 and the second interlayer insulation film 26 by reaction between NH₃ gas and Ta chemical vapor made by generating a precursor such as Ta(OC₂H₅)₅ (tantalum ethoxylate). Preferably, the deposition process of the TaON film 32 is controlled to be performed only on the surface of a wafer in a state in which the gas phase reaction is restricted, and NH₃ gas at 25 through 200 sccm is provided. Here, the TaON film 32 is preferably formed using a chemical vapor deposition method, for example, in a LPCVD (low pressure chemical vapor deposition) chamber in which a temperature of about 300 through 450° C. and pressure between about 0.2 to 0.4 torr are maintained. Here, since the precursor such as Ta(OC₂H₅)₅ is in a liquid state, the precursor is converted to a vapor state and supplied to the LPCVD chamber. The precursor is converted to Ta chemical vapor using the following method. That is, the amount of flow of the precursor is controlled by a flow controller such as a MFC (mass flow controller), and the precursor is supplied to a vaporization pipe or vaporizer. Then, the precursor supplied to the vaporization pipe or vaporizer is vaporized at a temperature of about 160 to 190° C. and becomes a Ta chemical vapor. Next, the Ta chemical vapor is supplied to the LPCVD chamber to form the TaON film 32.

Then, as shown in FIG. 2D, the amorphous TaON film 32 undergoes a batch type electric furnace annealing or RTP (rapid thermal processing) in an atmosphere of an oxygen-containing gas, for example, in an atmosphere of N₂O or O₂ gas and at a temperature of about 750 to 900° C. Accordingly, the TaON film 32, which was in an amorphous state, becomes a TaON film 32a in a crystallized state. When the TaON film 32a is crystallized, the combination force of the TaON film increases and thus contracts so that the overall thickness decreases by a predetermined value. Also, even though a high temperature heat treatment for crystallizing the TaON film 32 is performed, since the lower electrode 30 exhibits a superior high temperature resistance and is formed of a Ta metal film having low reactivity with oxygen, further natural oxidation does not generate. Next, an upper electrode 34 formed of a TiN barrier and a doped polysilicon film is formed on the crystallized TaON film 32a.

Also, the present invention is not limited to the above preferred embodiment. For example, in the present preferred embodiment, the Ta metal film 28 is crystallized after being deposited and then the TaN film 29 is formed. However, the same effect can be obtained when a heat treatment is performed after the Ta metal film 28 and the TaN film 29 are sequentially formed.

As described above, according to the invention, the capacitor uses a TaON film as a dielectric film, the lower electrode is formed of a Ta metal film which has a superior high temperature resistance and is less prone to oxidation. Accordingly, when a high temperature process to crystallize the TaON film is performed, a natural oxide film hardly generates on the surface of the lower electrode. Further, since a TaN film serving as an oxygen barrier is further deposited on the surface of the Ta metal film, movement of oxygen during a heat treatment can be restricted.

It is to be understood that the foregoing descriptions and specific embodiments shown herein are merely illustrative of the best mode of the invention and the principles thereof, and that modifications and additions may be easily made by those skilled in the art without departing for the spirit and scope of the invention, which is therefore understood to be limited only by the scope of the appended claims.

What is claimed is:

1. A capacitor in a semiconductor device comprising:
a semiconductor substrate;
a lower electrode formed of a Ta metal film on the semiconductor substrate;
a TaON dielectric film formed on the lower electrode; and
an upper electrode formed on the TaON dielectric film.

2. The capacitor as claimed in claim 1, further comprising an oxygen barrier between the lower electrode and the TaON film.

3. The capacitor as claimed in claim 2, wherein the oxygen barrier is a TaN film.

4. The capacitor as claimed in claim 1, wherein the upper electrode is formed of a deposed TiN film and a doped polysilicon film.

5. A method of manufacturing a capacitor in a semiconductor device, comprising the steps of:
forming a Ta film on a semiconductor substrate;
forming a lower electrode by patterning a portion of the Ta metal film;
forming a TaON film on the lower electrode; and
forming an upper electrode on the TaON film.

6. The method as claimed in claim 5, wherein the step of forming the Ta film comprises:
depositing a Ta metal film on the semiconductor substrate; and
crystallizing the Ta metal film.

7. The method as claimed in claim 6, wherein the Ta metal film is formed in a direct current magnetron sputtering chamber.

8. The method as claimed in claim 7, wherein Ar gas at a flow rate of about 10 to 1000 sccm is supplied to the sputtering chamber and RF power of about 30 to 40 W is applied.

9. The method as claimed in claim 7, wherein, in the step of crystallizing the Ta metal film comprises:
supplying N₂ gas or NH₃ gas at about 10 to 1000 sccm to the sputtering chamber; and
heat treating at a temperature of about 600 to 750° C. for about 5 to 30 minutes.

10. The method as claimed in claim 7, wherein the step of crystallizing the Ta metal film comprises:
exciting a plasma in the sputtering chamber; and
heat treating at a temperature of about 300 to 500° C. for about 1 to 30 minutes.

11. The method as claimed in claim 6, which further comprises:
forming a TaN film on the surface of the Ta metal film by nitrifying the surface of the Ta metal film, the forming a TaN film step being between the step of depositing the Ta metal film and the step of crystallizing the Ta metal film, or between the step of crystallizing the Ta metal film and the step of forming the lower electrode.

12. The method as claimed in claim 7, which further comprises:
forming a TaN film on the surface of the Ta metal film by nitrifying the surface of the Ta metal film, the forming a TaN film step being provided between the step of depositing the Ta metal film and the step of crystallizing the Ta metal film, or between the step of crystallizing the Ta metal film and the forming the lower electrode.

13. The method as claimed in claim 11, wherein the step of forming the TaN film comprises:
supplying NH₃ gas at about 10 to 1000 sccm is to the sputtering chamber; and heat treating at a temperature of about 300 to 450° C. and a pressure of about 0.01 to 0.4 torr.

14. The method as claimed in claim 5, wherein forming the TaON film is performed by using a surface chemical reaction between Ta chemical vapor and NH₃ gas in a LPCVD chamber in which a temperature of about 300 to 450° C. and a pressure of about 0.2 to 0.4 torr are maintained.

15. The method as claimed in claim 5, which further comprises:
crystallizing the TaON film between the step of forming the TaON film and the step of forming the upper electrode.

16. The method as claimed in claim 15, wherein the step of crystallizing the TaON film comprises:
electric furnace annealing or RTP annealing in an atmosphere of oxygen containing gas and at a temperature of about 750 to 900° C.

17. A method of manufacturing a capacitor in a semiconductor device comprising the steps of:
depositing a Ta metal film on a semiconductor substrate;
crystallizing the Ta metal film;
forming a lower electrode by pattering a portion of the Ta metal film;
forming a TaON film on the lower electrode;
crystallizing the TaON metal film; and
forming an upper electrode on the TaON film,
wherein a step of forming a TaN film on the surface of the Ta metal film is provided between the step of depositing the Ta metal film and the step of crystallizing the Ta metal film, or between the step of crystallizing the Ta metal film and the step of forming the lower electrode.

18. The method as claimed in claim 17, wherein the steps of depositing the Ta metal film, crystallizing the Ta metal film, and forming the TaN film are performed in-situ.

19. The method as claimed in claim 18, wherein the Ta metal film is formed in a direct current magnetron sputtering chamber.

20. The method as claimed in claim 19, which further comprises:
forming a plasma inside the chamber by supplying Ar gas at about 10 to 1000 sccm to the chamber and applying an RF power of about 30 to 400 W.

21. The method as claimed in claim 19, wherein the step of crystallizing the Ta metal film comprises:
supplying N₂ gas or NH₃ gas at about 10 to 1000 sccm to the chamber; and
heat treating at a temperature of about 600 to 750° C. for about 5 to 30 minutes.

22. The method as claimed in claim 19, wherein the step of crystallizing the Ta metal film comprises:
exciting a plasma in the chamber; and
heat treating at a temperature of about 300 to 500° C. for about 5 to 30 minutes.

23. The method as claimed in claim 19, wherein the step of forming the TaN film comprises:
supplying NH₃ gas at about 10 to 1000 sccm to the chamber; and
heat treating at a temperature of about 300 to 450° C. and a pressure of about 0.01 to 0.4 torr.

24. The method as claimed in claim 1&, wherein the TaON film is formed by a surface chemical reaction between Ta chemical vapor and NH₃ gas in an LPCVD chamber in which a temperature of about 300 to 450° C. and a pressure of about 0.2 to 0.4 torr are maintained.

25. The method as claimed in claim 17, wherein the step of crystallizing the TaON film comprises:
electric furnace annealing or RTP annealing in an atmosphere of oxygen containing gas and at a temperature of about 750 to 900° C.
